(19) United States
(12) Patent Application Publication
(10) Pub. No.: US 2005/0130383 A1
(43) Pub. Date: Jun. 16, 2005

(54) SILICIDE RESISTOR IN BEOL LAYER OF SEMICONDUCTOR DEVICE AND METHOD

(75) Inventors: Ramachandra Divakaruni, Ossining, NY (US); Jay W. Strane, Chester, NY (US)

Correspondence Address: HOFFMAN WARNICK & D'ALESSANDRO, LLC, 3 E-COMM SQUARE, ALBANY, NY, 12207, US

(73) Assignee: INTERNATIONAL BUSINESS MACHINES CORPORATION, Armonk, NY (US)

(21) Appl. No.: 10/707,388

(22) Filed: Dec. 10, 2003

(51) Int. Cl. H01L 21/20

(52) U.S. Cl. 438/384

(57) ABSTRACT

A suicide resistor for inclusion in a BEOL layer, and a method of forming the same that provides few additional manufacturing steps. The method allows formation of a passive resistor during BEOL processing without high temperature anneals that would damage other BEOL wiring structures. In particular, the method includes forming a silicide over a polysilicon base in a trough, where the silicide provides the desired resistivity and has a silicidation temperature less than a damaging temperature of the plurality of BEOL layers.

### BACKGROUND OF INVENTION

The present invention relates generally to semiconductor devices, and more particularly to a resistive metallurgical wiring level of a semiconductor integrated circuit and a method of forming the same.

High resistance passive elements are used extensively in semiconductor integrated circuits. Common devices used to create these high resistance elements are silicide resistors. These silicide resistors use lines of doped polysilicon to achieve the desired resistance. Silicide resistors are created early in the semiconductor chip processing before the formation of wiring levels during front-end-of-line (FEOL) processing. The high thermal requirements for activation annealing of the dopants (excess of 900° C.) in the formation of polysilicon devices are too large for typical chip wiring or back-end-of-line (BEOL) structures to withstand damage. The ability to create high resistance elements in the BEOL processing has some advantages in chip design such as reduced chip size due to the decrease in wiring needed to access the resistors and the ability to make design modifications in only the top design layers.

In view of the foregoing, there is a need in the art for a technique to incorporate high resistance elements in the BEOL with few additional manufacturing steps.

### SUMMARY OF INVENTION

The invention includes a silicide resistor for inclusion in the BEOL, and a method of forming the same that provides few additional manufacturing steps. The method also allows formation of a passive resistor during BEOL processing without high temperature anneals that would damage other BEOL wiring structures. In particular, the method includes forming a silicide over a polysilicon base in a trough, where the silicide provides the desired resistivity and has a silicidation temperature less than a damaging temperature of the plurality of BEOL layers.

A first aspect of the invention is directed to a method for generating a silicide resistor in one of a plurality of back-end-of-line (BEOL) layers without using high temperature processing, the method comprising the steps of: forming a trough in an inter-layer dielectric (ILD) layer of the plurality of BEOL layers; depositing a polysilicon layer over the trough; etching the polysilicon layer to have a top surface below a surface of the ILD layer within the trough to form a polysilicon base in the trough; depositing a first metal; annealing to form a silicide layer from the first metal; and planarizing to form a silicide section within the trough to generate the silicide resistor.

In a second aspect of the invention is provided a resistor for a semiconductor device, the resistor comprising: a silicide section positioned in one of a plurality of back-end-of-line (BEOL) layers; wherein the silicide section has a silicidation temperature less than a damaging temperature of the plurality of BEOL layers.

A third aspect of the invention is directed to a semiconductor device comprising: a silicide resistor in one of a plurality of back-end-of-line (BEOL) layers, the silicide resistor including a silicide section having a silicidation temperature less than a damaging temperature of the plurality of BEOL layers.

The foregoing and other features of the invention will be apparent from the following more particular description of embodiments of the invention.

### BRIEF DESCRIPTION OF DRAWINGS

The embodiments of this invention will be described in detail, with reference to the following figures, wherein like designations denote like elements, and wherein:

FIG. 1 shows a first step of a method of forming a silicide resistor according to the invention.

FIG. 2 shows a second step of the method.

FIG. 3 shows a third step of the method.

FIG. 4 shows an optional step of the method.

FIG. 5 shows a fourth step of the method.

FIG. 6 shows a fifth step of the method.

FIG. 7 shows a sixth step of the method and a silicide resistor and semiconductor device according to the invention.

### DETAILED DESCRIPTION

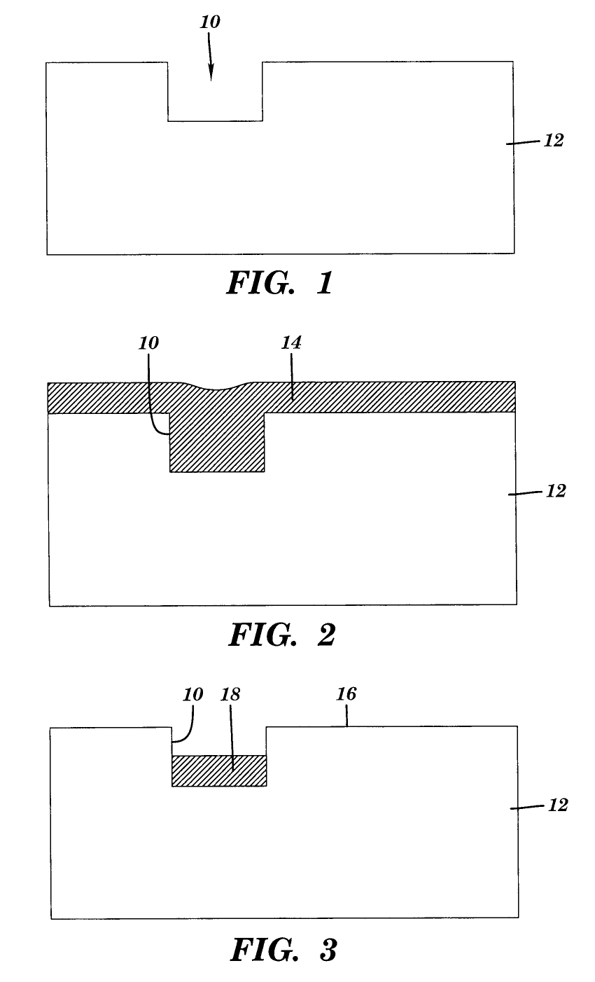

With reference to the accompanying drawings, FIG. 1 illustrates a first step of a method for generating a silicide resistor 100 (FIG. 8) according to the invention. In FIG. 1, a trough 10 is formed in an inter-layer dielectric (ILD) layer 12 of a plurality of back-end-of-line (BEOL) layers (not shown for clarity—above and/or below ILD layer 12) such as via layer and/or metal layers. Formation of trough 10 may be made by patterning and etching in a conventional fashion. ILD layer 12 may be any now known or later developed dielectric layer used with BEOL layer such as silicon dioxide SiO2 (hereinafter “oxide”), SiLK® available from Dow Chemical, boron doped oxide, a high-k dielectric, chemical vapor deposited (CVD) low-k material, FSG, FTEOS or other dielectric known in the industry. ILD layer 12 may be positioned above another dielectric layer (not shown) that may include wiring therein. It should be recognized, however, that ILD layer 12 may be any BEOL layer, e.g., it could be any layer containing a via and/or a metal.

Next, as shown in FIG. 2, trough 10 is filled via depositing of a polysilicon layer 14 over trough 10. As shown in FIG. 3, polysilicon layer 14 is then etched back below a surface 16 of ILD layer 12 within trough 10 to form a polysilicon base 18 therein for silicide resistor 100 (FIG. 8). Actual etching chemistry will have appropriate selectivity to the ILD layer 12 material.

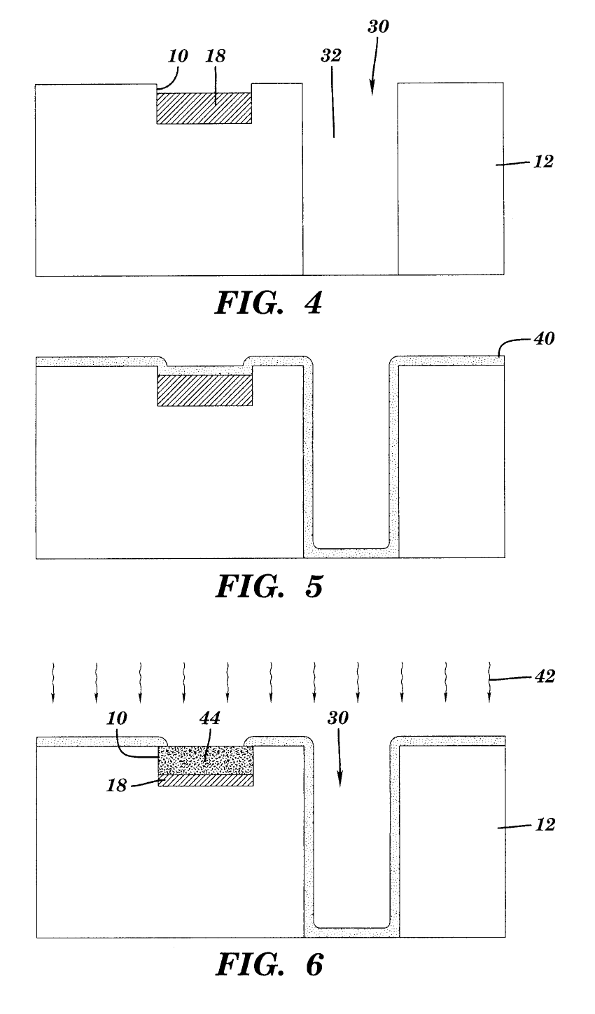

FIG. 4 shows a step of forming a conventional BEOL wiring structure 30 in ILD layer 12. Conventional BEOL wiring structure 30 could be, for example, a via to underlying wiring layers or a simple wire.

Next, as shown in FIG. 5, a first metal 40 is deposited. First metal 40 may be any metal or alloy capable of forming a silicide having the desired resistivity, and a silicidation temperature that is less than a damaging temperature of a structure in the plurality of BEOL layers. “Damaging temperature” is a temperature at which damage is probable to occur to a structure in any of the plurality of BEOL layers. Example first metals 40 may include one of: cobalt (Co), palladium (Pd), platinum (Pt) and nickel (Ni). First metal 40 covers trough 10 area and polysilicon base 18, and structure 30, e.g., via opening 32.

Next, as shown in FIG. 6, an anneal 42 is conducted to form a silicide layer 44 from first metal 40 within trough 10. Silicide layer 44 forms a silicide section 46 (FIG. 8) over polysilicon base 18 within trough 10. During anneal 42, polysilicon base 18 is, at least in part, consumed by the formation of silicide section 46. As a result, although shown, the resulting silicide resistor 100 (FIG. 8) may not include polysilicon base 18. Although not necessary, anneal 42 may be provided as part of a dual-purpose anneal, e.g., along with an anneal in a nitridizing ambient used to complete the metal barrier for the interconnect region. For the above listed first metals 40, the anneal temperature ranges (i.e., silicidation temperatures of first metals) are as follows: cobalt (Co) approximately 600-700° C.; palladium (Pd) approximately 200-500° C.; platinum (Pt) approximately 300-600° C.; nickel (Ni) approximately 400-600° C. for nickel silicide (NiSi) and approximately 600-700° C. for di-nickel silicide (Ni₂Si). The resulting resistivity ranges of the above-identified silicides are as follows: cobalt silicide (CoSi) approximately 14-20 μ-ohms/cm; palladium silicide approximately 25-30 μ-ohms/cm; platinum silicide (PtSi) approximately 26-35 μ-ohms/cm; nickel silicide (NiSi) approximately 14-20 μ-ohms/cm; and di-nickel silicide (Ni₂Si) approximately 35-50 μ-ohms/cm.

For alternative BEOL wiring schemes that allow higher temperature processing, there are other material options for first metal 40 to create this resister. For example, using a more thermally stable BEOL wiring metal (e.g., tungsten (W)) instead of traditional aluminum (Al) or copper (Cu) as the wiring level would make possible many other silicide possibilities. Among the many possible refractory metal choices are molybdenum (Mo) and tungsten (W). Molybdenum silicide (MoSi₂) has resistivity range of 40-100-ohms/cm and forms at 400-700° C., and tungsten suicide (WSi₂) has a reisistivity of 6-15 μ-ohms/cm and forms at 600-700° C.

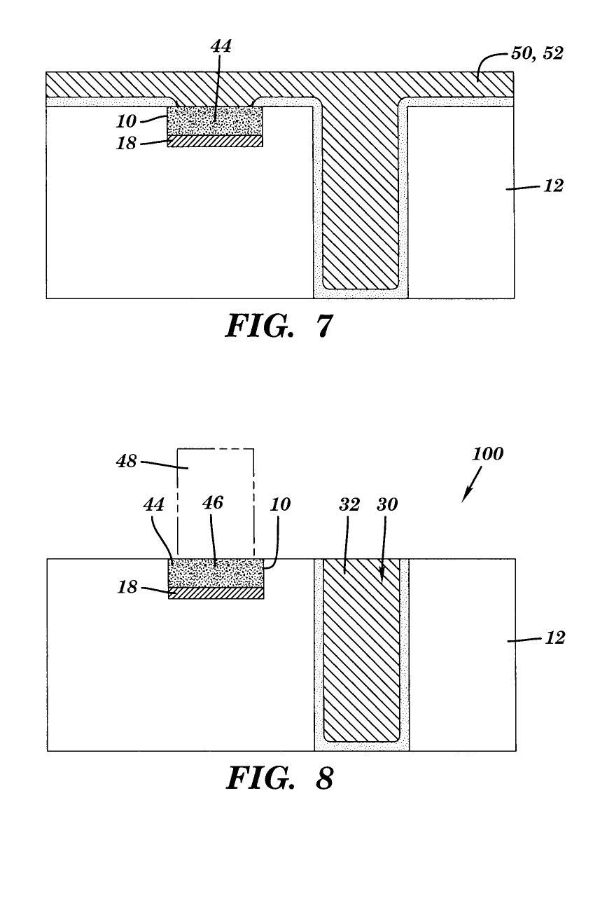

As shown in FIGS. 7 and 8, a final step includes planarizing to generate silicide resistor 100 (FIG. 8) and complete the damascene process for the BEOL wiring structures. As an optional step, a layer 50 of a second metal 52 may be deposited to form structure 30, e.g., a via or wire. Contact layer 50 includes any desirable metal compatible with the particular silicide 44 formed, e.g., tungsten (W), copper (Cu), aluminum (Al) or doped polysilicon. As shown in FIG. 8, a second part of this step includes planarizing to remove residuals of layer 50, i.e., second metal 52, and silicide layer 44 outside of trough 10. Planarization can be provided by any conventional polishing technique such as chemical mechanical polishing (CMP). Subsequent processing (not shown) to resistor formation may include forming a contact via (not shown) to silicide resistor 100 in a known fashion.

FIG. 8 illustrates a silicide resistor 100 in a semiconductor device according to the invention. Silicide resistor 100 includes a silicide section 46 positioned in one of a plurality of back-end-of-line (BEOL) layers, wherein the silicide section 46 has a silicidation temperature less than a damaging temperature of the plurality of BEOL layers. Silicide resistor 100 may also include a polysilicon base 18 positioned below silicide section 46 in the case where silicide section 46 does not consume all of the polysilicon. The resulting resistivity depends on the particular silicide formed. As noted above, ranges of the above-identified suicides are as follows: cobalt silicide (CoSi) approximately 14-20 μ-ohms/cm; palladium silicide approximately 25-30 μ-ohms/cm; platinum silicide (PtSi) approximately 26-35 μ-ohms/cm; nickel silicide (NiSi) approximately 14-20 μ-ohms/cm; and di-nickel silicide (Ni2Si) approximately 35-50 μ-ohms/cm. In view of the foregoing, silicide resistor 100 is generated without using high temperature processing that would damage other BEOL layer structure and is highly resistive. In addition, silicide resistor 100 is thermally stable at approximately 400° C.

While this invention has been described in conjunction with the specific embodiments outlined above, it is evident that many alternatives, modifications and variations will be apparent to those skilled in the art. Accordingly, the embodiments of the invention as set forth above are intended to be illustrative, not limiting. Various changes may be made without departing from the spirit and scope of the invention as defined in the following claims.

1. A method for generating a suicide resistor in one of a plurality of back-end-of-line (beol) layers without using high temperature processing, the method comprising the steps of:
forming a trough in an inter-layer dielectric (ILD) layer of the plurality of BEOL layers;
depositing a polysilicon layer over the trough;
etching the polysilicon layer to have a top surface below a surface of the ILD layer within the trough to form a polysilicon base in the trough;
depositing a first metal;
annealing to form a silicide layer from the first metal; and
planarizing to form a silicide section within the trough to generate the silicide resistor.

2. The method of claim 1, wherein the trough forming step includes patterning the ILD layer and etching to form the trough.

3. The method of claim 1, wherein the ILD layer includes one of: silicon dioxide (SiO2), SiLK, boron doped oxide, and a high-k dielectric.

4. The method of claim 1, further comprising the step of forming one of a via through the ILD layer, and a wire in the ILD layer.

5. The method of claim 1, wherein an anneal temperature is lower than a damaging temperature that would damage a structure in the plurality of BEOL layers.

6. The method of claim 1, wherein the first metal is one of: cobalt (Co), palladium (Pd), platinum (Pt), nickel (Ni), molybdenum (Mo) and tungsten (W).

7. The method of claim 1, further comprising the step of forming a contact to the silicide section.

8. The method of claim 1, wherein the silicide section includes palladium silicide (PdSi) and has a resistivity of no less than approximately 25 μ-ohms/cm and no greater than approximately 30 μ-ohms/cm.

9. The method of claim 1, wherein the silicide section includes platinum silicide (PtSi) and has a resistivity of no less than approximately 26 μ-ohms/cm and no greater than approximately 35 μ-ohms/cm.

10. The method of claim 1, wherein the silicide section includes nickel silicide (NiSi) and has a resistivity of no less than approximately 14 μ-ohms/cm and no greater than approximately 20 μ-ohms/cm.

11. The method of claim 1, wherein the suicide section include di-nickel silicide (Ni₂Si) and has a resistivity of no less than approximately 35 μ-ohms/cm and no greater than approximately 50 μ-ohms/cm.

12. A resistor for a semiconductor device, the resistor comprising:
a silicide section positioned in one of a plurality of back-end-of-line (BEOL) layers;
wherein the silicide section has a silicidation temperature less than a damaging temperature of the plurality of BEOL layers.

13. The resistor of claim 12, wherein the silicide section includes cobalt silicide (CoSi) and has a resistivity of no less than approximately 14 μ-ohms/cm and no greater than approximately 20 μ-ohms/cm.

14. The resistor of claim 12, wherein the silicide section includes palladium silicide (PdSi) and has a resistivity of no less than approximately 25 μ-ohms/cm and no greater than approximately 30 μ-ohms/cm.

15. The resistor of claim 12, wherein the silicide section includes platinum silicide (PtSi) and has a resistivity of no less than approximately 26 μ-ohms/cm and no greater than approximately 35 μ-ohms/cm.

16. The resistor of claim 12, wherein the suicide section includes nickel silicide (NiSi) and has a resistivity of no less than approximately 14 μ-ohms/cm and no greater than approximately 20 μ-ohms/cm.

17. The resistor of claim 12, wherein the silicide section includes di-nickel silicide (Ni₂Si) and has a resistivity of no less than approximately 35 μ-ohms/cm and no greater than approximately 50 μ-ohms/cm.

18. The resistor of claim 12, wherein the silicide section includes one of molybdenum silicide (MoSi₂) and tungsten silicide (WSi₂).

19. The resistor of claim 12, further comprising a polysilicon base positioned below the silicide section.

20. A semiconductor device comprising:
a silicide resistor in one of a plurality of back-end-of-line (BEOL) layers, the silicide resistor including a silicide section having a silicidation temperature less than a damaging temperature of the plurality of BEOL layers.
